(19) United States
(12) Patent Application Publication
(10) Pub. No.: US 2019/0228200 A1
(43) Pub. Date: Jul. 25, 2019

(54) ELECTRONIC DEVICE AND IMAGE CAPTURE MODULE THEREOF

(71) Applicant: Gingy Technology Inc., Hsinchu City (TW)

(72) Inventors: WEI-CHUN CHUNG, Hsinchu City (TW); JEN-CHIEH WU, Hsinchu City (TW)

(21) Appl. No.: 16/170,749

(22) Filed: Oct. 25, 2018

Related U.S. Application Data
(60) Provisional application No. 62/620,985, filed on Jan. 23, 2018.

(30) Foreign Application Priority Data
Mar. 9, 2018 (CN) 201820324218.6

(51) Int. Cl. G06K 9/00; H01L 27/32; H01L 27/146; G02B 6/42

(52) U.S. Cl. CPC G06K 9/0004; G06K 9/00046; H01L 27/323; H01L 27/3234; G02B 6/4215; H01L 27/1462; H01L 27/14678; G02B 6/4298; H01L 27/14625

(57) ABSTRACT

An image capture module includes a light-permeable element, an image capture element, and a light-guiding element. The light-permeable element has a surface in contact with an environmental medium. The image capture element has a sensing pixel array. The light-guiding element is disposed at a position between the light-permeable element and the image capture element, and has a plurality of optical fibers. Each of the optical fibers has a core part and a shell part that is surroundingly disposed around the core part, the shell part is doped with a plurality of light-absorbing particles, and each of the optical fibers has a numerical aperture smaller than or equal to 0.7. An electronic device includes the image capture module and is configured to capture an image of an object.

### CROSS-REFERENCE TO RELATED PATENT APPLICATION

This application claims priority from the U.S. Provisional Patent Application Ser. No. 62/620,985 filed Jan. 23, 2018, and China application Ser. No. 201820324218.6 filed on Mar. 9, 2018. The entirety of each of the above-mentioned patent applications is hereby incorporated by reference herein and made a part of this specification.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to an electronic device and a photoelectric module, and more particularly to an electronic device and an image capture module thereof.

### BACKGROUND OF THE DISCLOSURE

Conventional optical biometric systems can be used to detect and recognize faces, voices, irises, retinas or fingerprints. With an optical fingerprint identification system as an example, an image capturing device in the optical fingerprint identification system generally includes a substrate, a light-emitting element, a light-permeable element, a light-guiding element, and an image sensor; in which, the light-emitting element and the image sensor are disposed on the substrate, the light-guiding element is disposed on the light-emitting element and the image sensor, and the light-permeable element is disposed on the light-guiding element.

The light beam generated by the light-emitting element is transmitted to the light-permeable element through the light-guiding element, the light beam is totally reflected by the interface of the light-permeable element and the environmental medium, and then received by the image sensor. Since there are a plurality of irregular ridges and valleys on a finger, when a user places the finger on the light-permeable element, the ridges contact the light transmitting element, while the valleys do not. Therefore, the ridges contacting the light-permeable element will compromise the total reflection of the light beam in the light-permeable element, whereas the valleys not contacting the light-permeable will not affect the total reflection of the light beam, so that the fingerprint captured by the image sensor has dark lines corresponding to the ridges and bright lines corresponding to the valleys. Subsequently, a user identity can be determined by processing the fingerprint captured by the image sensor through an image processing device.

However, crosstalk is often produced when the light beam reflected by the light-permeable element projects toward the image sensor through the light-guiding element, which lowers the contrast ratio of the dark line regions and the bright line regions, and negatively affects the precision of the bio-recognition.

### SUMMARY OF THE DISCLOSURE

In response to the above-referenced technical inadequacies, the present disclosure provides an electronic device and an image capture module thereof that can solve the issues relating to crosstalk and imprecision in biometric recognition when signal beams are projected to an image capture element through a light-guiding element.

In one aspect, the present disclosure provides an image capture module including a light-permeable element, an image capture element, and a light-guiding element. The light-permeable element has a surface in contact with an environmental medium. The image capture element has a sensing pixel array. The light-guiding element is disposed at a position between the light-permeable element and the image capture element, and has a plurality of optical fibers. Each of the optical fibers has a core part and a shell part that is surroundingly disposed around the core part, the shell part is doped with a plurality of light-absorbing particles, and each of the optical fibers has a numerical aperture smaller than or equal to 0.7. A light beam transmitted in the light-permeable element is reflected by the surface to form a signal beam that projects toward the optical fibers, and the signal light beam is then transmitted by the optical fibers to respectively form a plurality of sub-signal beams that project toward the sensing pixel array.

In an exemplary embodiment of the invention, the present disclosure provides an image capture module including a light-permeable element, an image capture element, and a light-guiding element. The light-permeable element has a surface in contact with an environmental medium. The image capture element has a sensing pixel array. The light-guiding element is disposed at a position between the light-permeable element and the image capture element, and includes a plurality of optical fibers and a light-absorbing medium that encloses the plurality of optical fibers, the light acceptance angle of a light incident surface of each of the optical fibers being smaller than 45°.

In an exemplary embodiment of the invention, the present disclosure provides an electronic device including the above-mentioned image capture module, the image capture module being configured to capture an image of an object.

An advantage of the present disclosure lies in that the electronic device and image capture module thereof can prevent crosstalk between signal beams reflected by different surface regions of the light-permeable element through the features of “the numerical apertures of each of the optical fibers of the light-permeable element are smaller than or equal to 0.7,” and “the shell part of the optical fibers are doped with the light-absorbing particles” or “the light-guiding element has the light-absorbing medium that encloses the plurality of optical fibers,” so that the contrast ratio of an image and the bio-recognition precision of an object can be effectively improved.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the detailed description and the accompanying drawings, in which:

FIG. 1 is a fragmentary sectional view of an image capture module according to one embodiment of the present disclosure;

FIG. 2 is a partial enlarged view of region II in FIG. 1 of the image capture module according to one embodiment of the present disclosure;

FIG. 3 is a graph showing the flux distribution of a signal beam on an image capture element when numerical apertures of a plurality of optical fibers of a light-guiding element is 0.1 according to one embodiment of the present disclosure;

FIG. 4 is a graph showing the flux distribution of the signal beam on the image capture element when the numerical apertures of the optical fibers of the light-guiding element is 0.25 according to one embodiment of the present disclosure;

FIG. 5 is a graph showing the flux distribution of the signal beam on the image capture element when the numerical apertures of the optical fibers of the light-guiding element is 0.5 according to one embodiment of the present disclosure;

FIG. 6 is a graph showing the flux distribution of the signal beam on the image capture element when the numerical apertures of the optical fibers of the light-guiding element is 1 according to one embodiment of the present disclosure;

FIG. 7 is a fragmentary sectional view of the image capture module according to another embodiment of the present disclosure; and

FIG. 8 is a fragmentary sectional view of the image capture module according to yet another embodiment of the present disclosure.

FIG. 9 is a fragmentary sectional view of the image capture module according to yet another embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

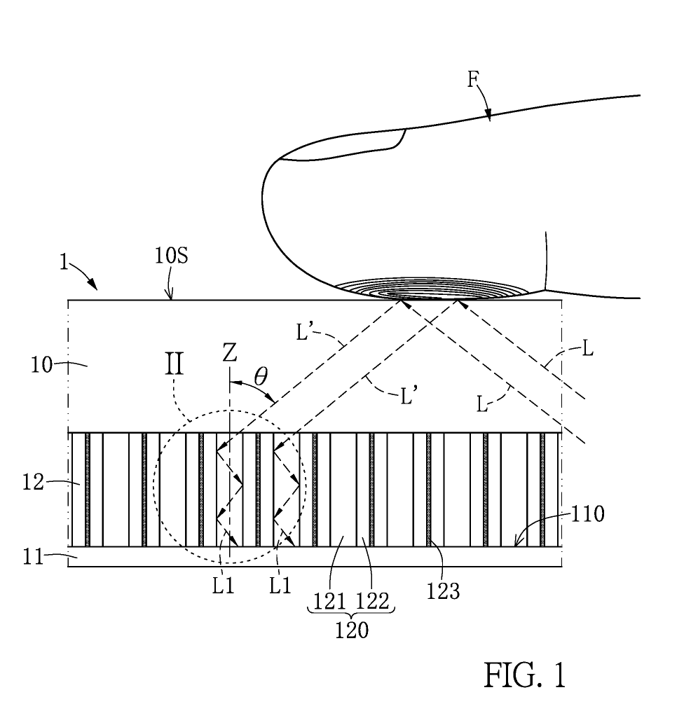

Reference is made to FIG. 1, which is a fragmentary sectional view of an image capture module according to an embodiment of the present disclosure. One embodiment of the present disclosure provides an image capture module 1 that can be applied in an electronic device to capture an image of an object F for biometric recognition. The electronic device can be a biometric scanner such as a fingerprint identification device, a palm print identification device, or an eye tracking device, etc.

The image capture module 1 is used in an environmental medium such as air, water, or other kinds of environmental mediums. The object F may be a finger, palm, wrist or eyes of a user, and the image captured by the image capture module 1 may be that of a fingerprint, a palm print, veins, retinas, or irises of a user, but are not limited by that disclosed in the present disclosure.

As shown in FIG. 1, the image capture module 1 according to one embodiment of the present disclosure includes a light-permeable element 10, an image capture element 11, and a light-guiding element 12, in which the light-guiding element 12 is disposed at a position between the light-permeable element 10 and the image capture element 12.

Specifically, the light-permeable element 10 has a surface 10S that is in contact with the environmental medium. When the image capture module 1 is applied in an optical biometric fingerprint identification system to capture images of fingerprints and/or veins, the surface 10S of the light-permeable element 10 can be pressed upon by a finger of the user for detection or recognition.

In addition, a light beam L is transmitted in the light-permeable element 10 through reflection of the surface 10S to form a signal beam L′ that projects toward the light-guiding element 12. The light beam L can be produced by a light-emitting element (not shown in the figures) such as a light-emitting diode, or originate from the ambient light. When the light beam L is projected to the surface 10S, the light beam L would be reflected to the light-guiding element 12. The light beam L can be a visible light, an infrared light, or other monochromatic lights, and is not limited in the present disclosure.

The material of the light-permeable element 10 can be selected from glass, polymethymethacrylate (PMMA), polycarbonate (PC), or other suitable materials. Furthermore, the light-permeable element 10 can be fixedly disposed on the light-guiding element 12 by optical adhesives or other fixing methods. In one embodiment of the present disclosure, the light-permeable element 10 can be an organic light emitting diode (hereinafter abbreviated as OLED) display or an OLED display having a touch control layer such as that disclosed in U.S. Pat. No. 62/533,632. It should be noted that OLED display with the touch control layer can have a protective layer on an outer surface thereof, and that the display panel can be rigid or flexible without being limited by the present disclosure. In one exemplary embodiment of the present disclosure, In one exemplary embodiment of the present disclosure, a light source of the image capture module 1 can be provided by light rays emitted from the OLED display. The image capture element 11 has a sensing pixel array 110 that faces toward the light-permeable element 10, so as to receive light beams emerging from the light-guiding element. The image capture element 11 can be such as a charge coupled device (CCD) or a complementary metal-oxide semiconductor (CMOS). However, in other embodiments of the present disclosure, the image capture element can also be other types of image sensing devices.

Referring to FIG. 1, in an exemplary embodiment, the light-guiding element 12 disposed between the light-permeable element 10 and the image capture element 11 includes a plurality of optical fibers 120. When the light beam L is reflected by a plurality of surface regions of the surface 10S of the light-permeable element 11, the signal beam L′ that projects toward the plurality of optical fibers 120 is formed, which then forms a plurality of sub-signal beams L1 through the transmission of the plurality of optical fibers 120, respectively.

Specifically, when the object F, such as a finger, contacts the surface 10S of the light-permeable element 10, the ridges on the finger contacts the surface 10S so that a portion of the light beam L projected to the surface 10S is reflected to form the signal beam L′. The signal beam L′ then projects toward the light-guiding element 12 and forms a plurality of sub-signal beams L1 through the transmission of the plurality of optical fibers 120, respectively.

The plurality of sub-signal beams L1 are projected to the sensing pixel array 110 of the image capture element 11 after being totally reflected in the optical fibers 120. Then, an image processing element processes the plurality of sub-signal beams L1 received by the image capture element 11 to obtain a fingerprint image of the finger (i.e., the object F).

In this embodiment, an optical axis Z of each of the optical fibers 120 is substantially parallel to the optical axis of the sensing pixel array 110. In other words, each of the optical fibers 120 extends from the inner surface of the light-permeable element 10 to the sensing pixel array 110 of the image capture element 11.

In addition, each of the optical fibers 120 has a core part 121 and a shell part 122 surroundingly disposed around the core part 121. It should be noted that there may be crosstalk between the signal beams L′ reflected by different surface regions of the surface 10S, which may reduce the contrast ratio of the image captured by the image capture element 11. Therefore, in this embodiment, the numerical apertures of each of the optical fibers 120 can be smaller than 0.7, so that the light acceptance angle of the light incident surface of each of the optical fibers 120 can be reduced.

Specifically, when the signal beam L′ enters the light incident surface of the optical fiber 120, the light incident angle 0 between the signal beam L′ and the optical axis Z of the optical fiber 120 should be smaller than or equal to the light acceptance angle, so as to allow the signal beam L′ to be transmitted to the light emergent surface of the optical fiber 120 through multiple total reflections of the signal beam L′ in the optical fiber 120, and be projected to the image capture element 11. Accordingly, the light acceptance angle of the optical fibers 120 can be reduced, and the crosstalk between the signal beams L′ reflected from different surface regions of the surface 10S can also be reduced.

More specifically, the numerical apertures of the optical fibers 120 is correlated to the light acceptance angle, and the light acceptance angle is correlated to the refraction coefficients of the core part 121 and the shell part 122 of each of the optical fibers 120.

In one embodiment of the present disclosure, the light acceptance angle of each of the optical fibers 120, the refraction coefficient of the light-permeable element 10, the refraction coefficient of the core part 121, and refraction coefficient of the shell part 122 satisfy the following relationship: nsin(θₘₐₓ)=(n₁²−n₂²)^{1/2}, where n is the refraction coefficient of the light-permeable element 10, n₁ is the refraction coefficient of the core part 121, n₂ is the refraction coefficient of the shell part 122, θₘₐₓ is the light acceptance angle at the light incident surface of the optical fibers 120.

In addition, the numerical apertures of the optical fibers 120 and the light acceptance angle at the light incident surface of the optical fibers 120 satisfy the following relationship: NA=nsin(θₘₐₓ), where NA is the numerical aperture of the optical fiber 120. Therefore, the smaller the numerical aperture NA of the optical fiber 120, the smaller the light acceptance angle of the optical fiber 120 will be.

In one embodiment of the present disclosure, the numerical aperture of each of the optical fibers 120 and the refraction coefficients of the core part 121 and the shell part 122 satisfy the following relationship: NA=(n₁²−n₂²)^{1/2}, where NA is the numerical aperture of the optical fiber 120, n₁ is the refraction coefficient of the core part 121, and n₂ is the refraction coefficient of the shell part 122.

It should be noted that in a conventional application of optical fibers in signal transmission, the optical fibers 120 can have a larger numerical aperture NA by adjusting the refraction coefficients of the core part 121 and the shell part 122, so that the optical power entering the optical fibers 120 can be increased. However, in the present disclosure, the larger the numerical aperture of the optical fiber 120, the larger the light acceptance angle will be, so that the signal beams L′ reflected from different surface regions of the surface 10S are more prone to enter the same one of the optical fibers 120. In other words, the signal beams L′ received by one of the optical fibers 120 not only includes the light beams reflected by the surface region corresponding to the one of the optical fibers 120, but also includes light beams reflected by the surface regions not corresponding to the one of the optical fibers 120. If the numerical aperture is larger, as in the conventional application of optical fibers, the contrast ratio or the resolution of the image captured by the image capture element 11 would be reduced, and the precision of bio-recognition would be negatively affected.

Therefore, different from the conventional application of optical fibers mentioned above, in the present disclosure, the numerical apertures of the optical fibers 120 should actually be smaller to reduce the light acceptance angle at the light incident surface of the optical fibers 120.

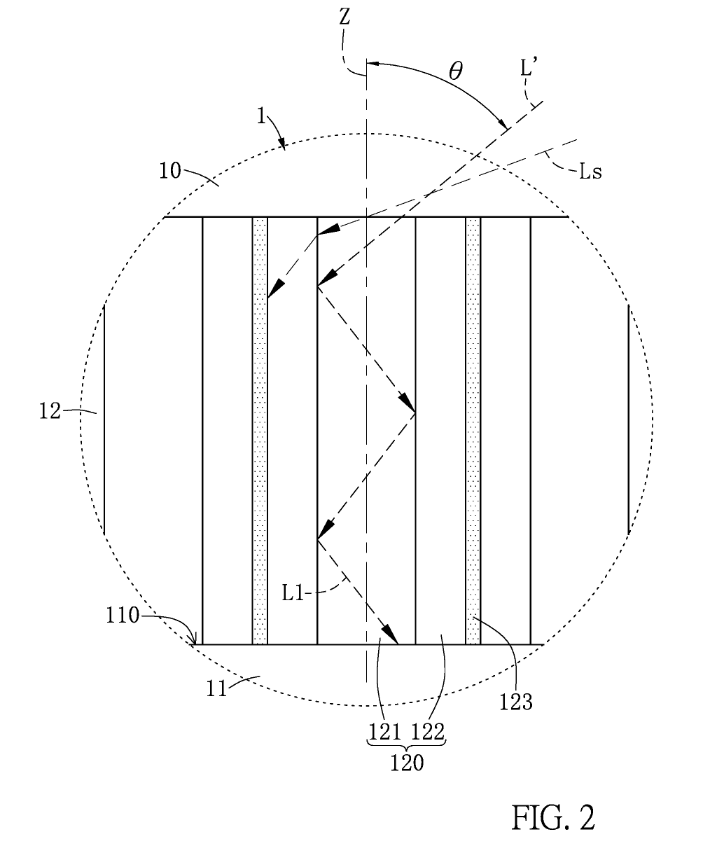

Reference is made to FIG. 2, which is a partial enlarged view of region II in FIG. 1 of the image capture module. As shown in FIG. 2, by adjusting the light acceptance angle of the optical fibers 120, only the light incident angle θ of the signal beam L′ reflected by a specific surface region corresponding to one of the optical fibers 120 will be smaller than the light acceptance angle, so that the light beam L′ can be transmitted to the image capture element 11 through the optical fiber 120.

In addition, other light beams Ls reflected by surface regions not corresponding to the optical fiber 120 (hereinafter referred to as stray light beams) enter the optical fiber 120 at a light incident angle larger than the light acceptance angle. The stray light beams Ls enter from the core part 121 into the shell part 122 to then penetrate out of the optical fiber 120. However, the stray light beams Ls penetrating out of the optical fiber 120 may also enter into another optical fiber 120 to be received by the image capture element 11.

Accordingly, in this exemplary embodiment, the light-guiding element 12 further includes a light-absorbing medium 123, and the plurality of optical fibers 120 are disposed within the light-absorbing medium 123 separately from each other. In this embodiment, the light-absorbing medium 123 encloses the plurality of optical fibers 120, and isolates the optical fibers 120 from each other, so that the stray light beams Ls penetrating out of the optical fiber 120 would be absorbed by the light-absorbing medium 123 and prevented from entering into other optical fibers 120. Therefore, the image quality can be improved by providing the light-absorbing medium 123 to enclose each of the optical fibers 120.

It should be noted that even though the numerical apertures of the optical fibers 120 are designed to be smaller in the present disclosure, since the light intensity of the sub-signal beams L1 transmitted to the image capture element 11 is lower but can reduce the crosstalk between the signal beams L′ reflected by different surface regions of the surface 10S, the contrast ratio or resolution of the image (of the object F) can be improved.

In this exemplary embodiment, the same effect can be achieved by having the numerical aperture of each of the optical fibers 120 be smaller than or equal to 0.7, or having the light acceptance angle at the light incident surface of the optical fibers 120 be smaller than 60°. Furthermore, the refraction coefficient n₁ of the core part 121 and the refraction coefficient n₂ of the shell part 122 should satisfy the following relationship: 0.1≤(n₁²−n₂²)^{1/2}≤0.7. In another embodiment of the present disclosure, the light acceptance angle at the light incident surface of the optical fibers 120 can also be smaller than 45°.

Therefore, in the embodiments of the present disclosure, by adjusting the numerical apertures of the optical fibers 120, and providing the light-absorbing medium 123 in the light-guiding element 12 to enclose the optical fibers 120, the crosstalk between the signal beams L′ reflected by different surface regions can be effectively reduced.

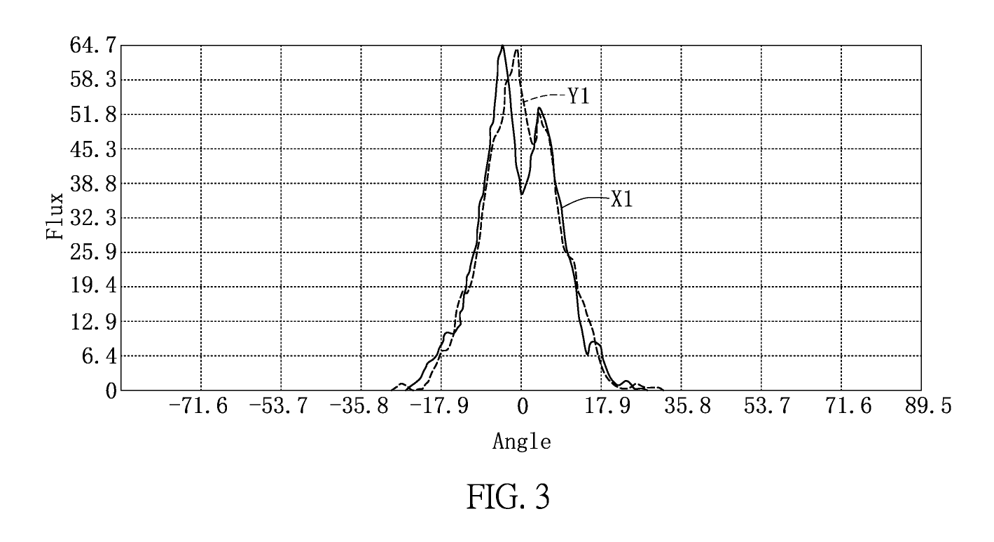

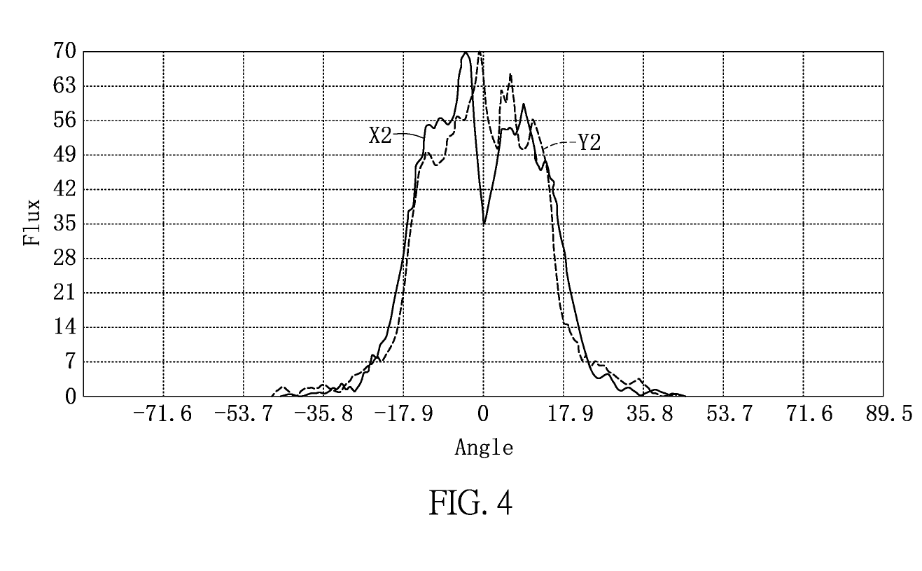

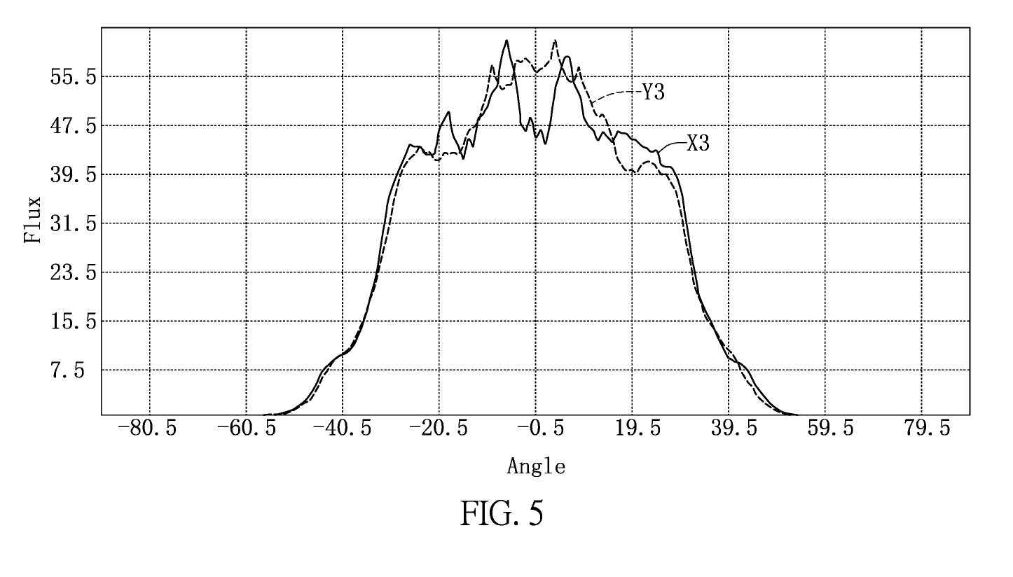

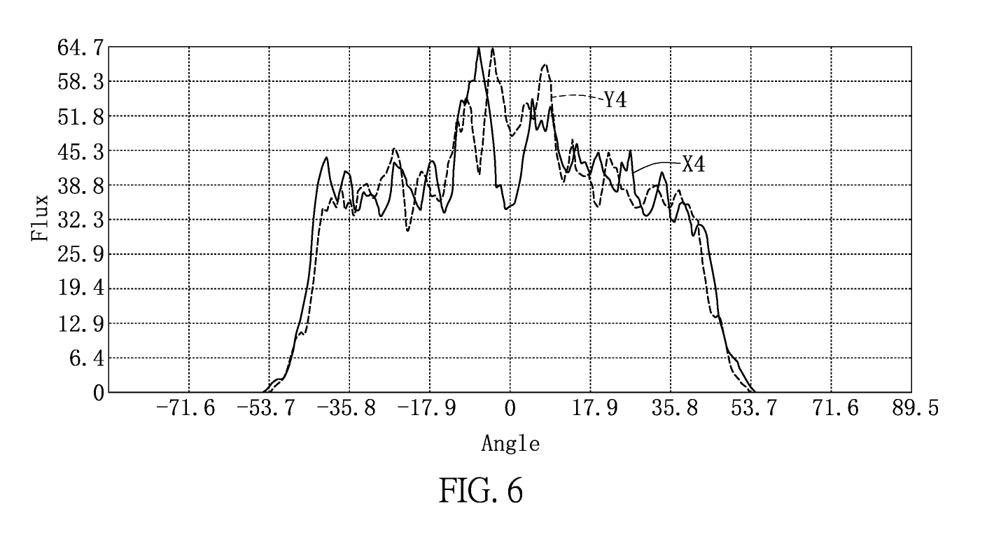

Reference is next made to FIG. 3 to FIG. 6, which respectively show the flux distribution of sub-signal beams when the numerical apertures are 0.1, 0.25, 0.5 and 1. The curves X1, X2, X3 and X4 in FIG. 3 to FIG. 6 represent the flux distribution of the sub-signal beams L1 on the X-axis after being projected to the sensing pixel array 110. Similarly, the curves Y1, Y2, Y3 and Y4 represent the sub-signal beams L1 on the Y-axis after being projected to the sensing pixel array 110.

As shown in FIG. 3 to FIG. 6, the full width at half maximum (hereinafter abbreviated as FWHM) of the curves X1, X2, X3 and X4 and the FWHM of the curves Y1, Y2, Y3 and Y4 decrease along with the decrease of the numerical apertures. This can further prove that when the numerical apertures of the optical fibers 120 are smaller than 1, the crosstalk between the signal beams L′ can indeed be reduced. Furthermore, when the numerical apertures of the optical fibers 120 are smaller than 0.1, the flux distribution of the sub-signal beams L1 on the X-axis and Y-axis can be more concentrated. Therefore, in one embodiment of the present disclosure, when the numerical apertures of the optical fiber 120 ranges between 0.1 and 0.23, the contrast ratio or resolution of the image captured by the image capture element 11 can be significantly improved.

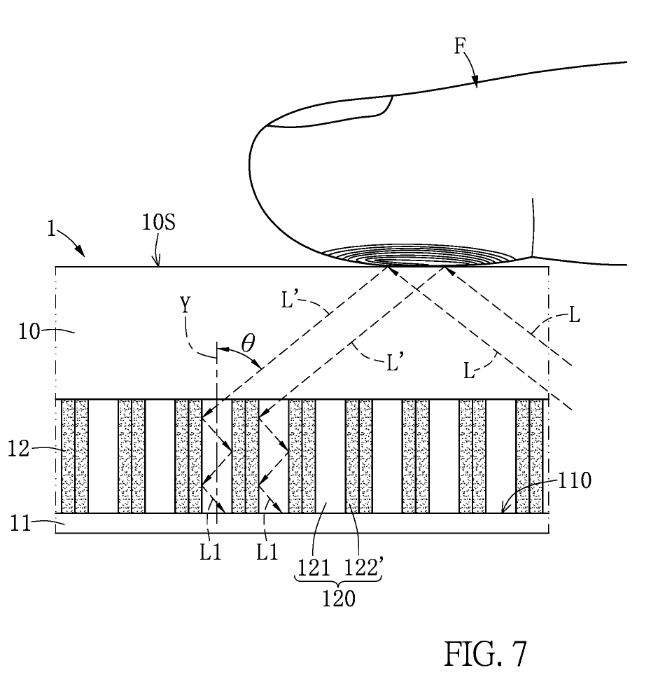

Reference is made to FIG. 7, which is a fragmentary sectional view of the image capture module according to another embodiment of the present disclosure. Elements/components in this embodiment that are similar to those of the previous embodiment will have the same reference numerals, and will not be further described. In this embodiment, the shell part 122′ of the optical fibers 120 is doped with a plurality of light-absorbing particles.

It should be noted that the refraction coefficient of the core part 121 and the refraction coefficient of the shell part 122′ still satisfies the following relationship: 0.1≤(n₁²−n₂²)^{1/2}≤0.7, where the shell part 122′ includes a substrate and is doped with the plurality of light-absorbing particles, and n₁ is the refraction coefficient of the core part 121, n₂ is the refraction coefficient of the shell part 122′ (the substrate). In other words, even though the shell part 122′ has the plurality of light-absorbing particles, the signal beam L1 can still be totally reflected in the optical fiber 120 by virtue of the refraction coefficients of the core part 121 and the shell part 122′.

Similar to the embodiment of FIG. 1, in this embodiment, the shell part 122′ has light-absorbing particles that can absorb the stray light beams Ls that enter the shell part 122′ from the core part 121, so as to prevent the stray light beams Ls from entering into other ones of the optical fibers 120. Accordingly, in this embodiment, the light-absorbing medium 123 enclosing the optical fibers 120 can be omitted.

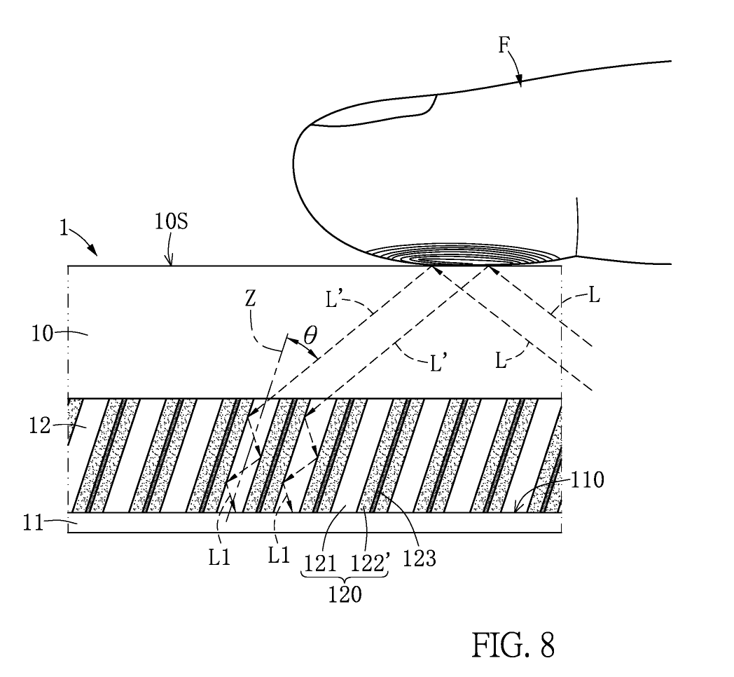

Reference is made to FIG. 8, which is a fragmentary sectional view of the image capture module according to yet another embodiment of the present disclosure. In this embodiment, in addition to the shell part 122′ of the optical fiber 120 having the light-absorbing particles, the light-guiding element 12 also has the light-absorbing medium 123 enclosing the optical fibers 120, so that crosstalk between signal beams L′ can be reduced, and that the image quality can be improved by preventing the stray light beams Ls from being received by the image capture element 11.

In addition, in this embodiment, the optical axis Z of each of the optical fibers 120 is not parallel with the optical axis of the sensing pixel array 110. Furthermore, the optical fibers 120 are disposed on the image capture element 11 at an inclined angle to correspond with the projecting direction of the signal beam L′. In other words, the optical fibers 120 are inclined toward the projecting direction of the signal beam L′ relative to the optical axis of the sensing pixel array 110, so that most of the signal beams L′ from the surface regions corresponding to the optical fiber 120 can enter the optical fiber 120 at the light incident angle θsmaller than the light acceptance angle to be received by the image capture element 11.

In other words, even though the numerical aperture of the optical fiber 120 is smaller so that there is less incident light of the signal beams L′, the amount of incident light of the signal beams L′ can be compensated for by the inclined disposition of the optical fibers 120.

Therefore, compared with the embodiments of FIG. 1 and FIG. 7, the image capture element 11 of the present embodiment can receive signal beams L′ with stronger intensity, so that the image (of the object F) captured by the image capture element 11 can have a higher brightness and a better image quality.

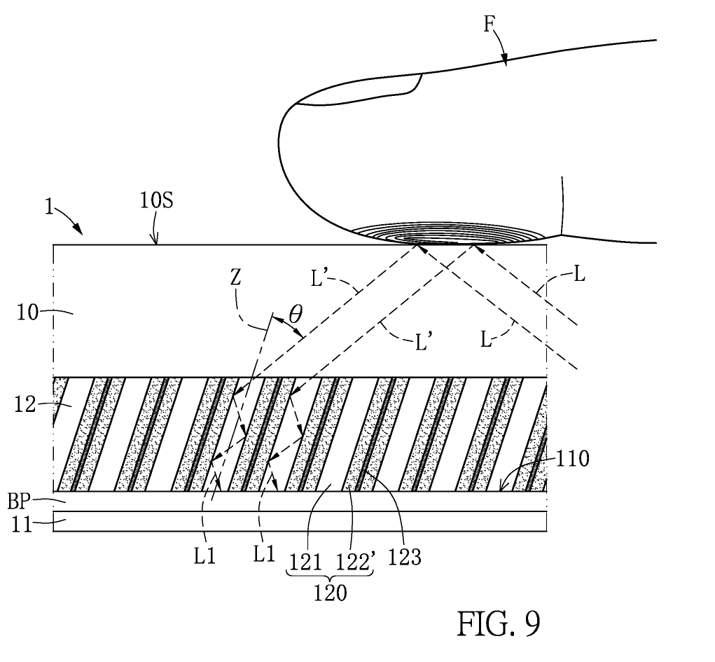

Reference is made to FIG. 9, which is a fragmentary sectional view of the image capture module according to yet another embodiment of the present disclosure. In the present embodiment, the image capture module 1 further include a band-pass filter BP disposed between the light-permeable element 10 and the image capture element 11. It should be noted that the band-pass filter BP can also be applied in the image capture modules 1 shown in FIGS. 1 and 7.

To be more specific, the band-pass filter BP is disposed between the light-guiding element 12 and the image capture element 11 so as to filter out stray light other than the signal beams L′. For instance, the band-pass filter BP can be disposed between the light-permeable element 10 and the light-guiding element 12 or between the light-guiding element 12 and the image capture element 11.

In this way, the bandpass filter BP can prevent ambient light from entering the image capture element 11 to cause signal interference. Accordingly, recognition accuracy of the image capture apparatus 1 can be improved by disposing the band-pass filter BP.

For instance, when the signal beams L′ is infrared light and has the wavelength that ranges from 800 nm to 900 nm, the bandpass filter BP is an infrared bandpass filter BP, only allowing the light beams having the wavelength that ranges from 800 nm to 900 nm to pass, but the present disclosure is not limited in this particular aspect. In conclusion, the electronic device and image capture module thereof according to the present disclosure can prevent crosstalk between the signal beams reflected by different surface regions of the light-permeable element through at least one of the technical features of “the numerical apertures of each of the optical fibers of the light-permeable element are smaller than or equal to 0.7” and “the light acceptance angle at the light incident surface of the optical fibers is smaller than 45°” in cooperation with at least one of the technical features of “the shell part of the optical fibers are doped with the light-absorbing particles” and “the light-guiding element has the light-absorbing medium that encloses the plurality of optical fibers,” so that the contrast ratio of the image and the bio-recognition precision of the object can be effectively improved.

On the other hand, even though the numerical apertures of the optical fibers 120 are designed to be smaller in the present disclosure, the amount of incident light of the signal beams L′ can be compensated for by the inclined disposition of the optical fibers 120. Therefore, the optical axis Z of the optical fiber 120 can be correspondingly inclined with the projecting direction of the signal beams L′, so that more of the signal beams L′ can be received for an improved image quality.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An image capture module comprising:
a light-permeable element having a surface in contact with an environmental medium;
an image capture element having a sensing pixel array; and
a light-guiding element disposed at a position between the light-permeable element and the image capture element, wherein the light-guiding element has a plurality of optical fibers, each of the optical fibers having a core part and a shell part that is surroundingly disposed around the core part, the shell part being doped with a plurality of light-absorbing particles, and each of the optical fibers having a numerical aperture smaller than or equal to 0.7;
wherein a light beam transmitted in the light-permeable element is reflected by the surface to form a signal beam that projects toward the optical fibers, and the signal light beam is then transmitted by the optical fibers to respectively form a plurality of sub-beams that project toward the sensing pixel array.

2. The image capture module according to claim 1, wherein the refraction coefficient of the core part and the refraction coefficient of the shell part satisfies the following relationship: 0.1≤(n₁²−n₂²)^{1/2} ≤0.7, in which n₁ is the refraction coefficient of the core part, and n₂ is the refraction coefficient of the shell part.

3. The image capture module according to claim 1, wherein the light acceptance angle of a light incident surface of each of the plurality of optical fibers is smaller than 60°.

4. The image capture module according to claim 1, wherein the light-guiding element further includes a light-absorbing medium, and the plurality of optical fibers are disposed within the light-absorbing medium separately from each other.

5. The image capture module according to claim 1, wherein the optical axis of each of the optical fibers are parallel with the optical axis of the sensing pixel array.

6. The image capture module according to claim 1, wherein the optical axis of each of the plurality of optical fibers are not parallel with the optical axis of the sensing pixel array.

7. The image capture module according to claim 1, wherein the light-permeable element is one of an organic light-emitting diode display and an organic light-emitting diode display having a touch control layer.

8. The image capture module according to claim 1, wherein the numerical aperture of each of the plurality of optical fibers ranges between 0.1 and 0.23.

9. The image capture module according to claim 1, further comprising a band-pass filter disposed between the light-permeable element and the image capture element.

10. The image capture module according to claim 1, further comprising a band-pass filter disposed between the light-guiding element and the image capture element.

11. An image capture module comprising:
a light-permeable element having a surface in contact with an environmental medium;
an image capture element having a sensing pixel array; and
a light-guiding element disposed at a position between the light-permeable element and the image capture element, wherein the light-guiding element includes a plurality of optical fibers and a light-absorbing medium that encloses the plurality of optical fibers, and the light acceptance angle of a light incident surface of each of the optical fibers is smaller than 45°;
wherein a light beam transmitted in the light-permeable element is reflected by the surface to form a signal beam that projects to the optical fibers, and the signal light beam is then transmitted by the optical fibers to respectively form a plurality of sub-signal beams that project toward the sensing pixel array.

12. The image capture module according to claim 11, wherein each of the optical fibers has a core part and a shell part that is surroundingly disposed around the core part, and the refraction coefficient of the core part and the refraction coefficient of the shell part satisfies the following relationship: 0.1≤(n₁²−n₂²)^{1/2}≤0.7, in which n₁ is the refraction coefficient of the core part, and n₂ is the refraction coefficient of the shell part.

13. The image capture module according to claim 11, wherein the numerical aperture of each of the plurality of optical fibers ranges between 0.1 and 0.23.

14. The image capture module according to claim 11, wherein the optical axis of each of the optical fibers are parallel with the optical axis of the sensing pixel array.

15. The image capture module according to claim 11, wherein the optical axis of each of the optical fibers are not parallel with the optical axis of the sensing pixel array.

16. The image capture module according to claim 11, wherein the light-permeable element is one of an organic light-emitting diode display and an organic light-emitting diode display having a touch control layer.

17. The image capture module according to claim 11, wherein each of the optical fibers has a core part and a shell part that is surroundingly disposed around the core part, the shell part includes a substrate that is doped with a plurality of light-absorbing particles, and the refraction coefficient of the core part and the refraction coefficient of the shell part satisfies the following relationship: 0.1≤(n₁²−n₂²)^{1/2}≤0.7, in which n₁ is the refraction coefficient of the core part, and n₂ is the refraction coefficient of the shell part.

18. The image capture module according to claim 11, further comprising a band-pass filter disposed between the light-permeable element and the image capture element.

19. The image capture module according to claim 11, further comprising a band-pass filter disposed between the light-guiding element and the image capture element.

20. An electronic device comprising:
the image capture module of claim 1, configured to capture an image of an object.
